(19) United States
(12) Patent Application Publication
(10) Pub. No.: US 2025/0088165 A1
(43) Pub. Date: Mar. 13, 2025

(54) ACOUSTIC WAVE DEVICE, FILTER, MULTIPLEXER, AND METHOD OF MANUFACTURING ACOUSTIC WAVE DEVICE

(71) Applicant: TAIYO YUDEN CO., LTD., Tokyo (JP)

(72) Inventor: Norihito FUJITA, Tokyo (JP)

(73) Assignee: TAIYO YUDEN CO., LTD., Tokyo (JP)

(21) Appl. No.: 18/824,825

(22) Filed: Sep. 4, 2024

(30) Foreign Application Priority Data
Sep. 13, 2023 (JP) 2023-148488

(51) Int. Cl. H03H 9/02; H03H 3/02; H03H 9/17; H03H 9/56

(52) U.S. Cl. CPC H03H 9/02094; H03H 3/02; H03H 9/02015; H03H 9/173; H03H 9/568; H03H 2003/021

(57) ABSTRACT

An acoustic wave device includes a piezoelectric layer provided with a part of the piezoelectric layer between lower and upper electrodes and having a through hole along a resonance region, an insertion film provided between the lower electrode and the piezoelectric layer and having a resistivity higher than those of the lower electrode and the upper electrode, a first film provided on a side of the upper electrode, a second film provided between the side surface of the upper electrode and the first film, and a third film provided between the side surface of the upper electrode and the second film or between the first film and the second film, a concentration of a first element of the third film being higher than that of the second film and a concentration of a second element of the third film being lower than that of the second film.

### FIELD

A certain aspect of the present disclosure relates to an acoustic wave device, a filter, a multiplexer, and a method of manufacturing an acoustic wave device.

### BACKGROUND

A filter and a duplexer using a piezoelectric thin-film resonator are known as a filter and a duplexer for a high frequency circuit of a radio terminal such as a portable terminal. A piezoelectric thin-film resonator is provided with a piezoelectric layer provided on a substrate, and a lower electrode and an upper electrode provided on the substrate with the piezoelectric layer interposed therebetween. A region where the lower electrode and the upper electrode face each other with the piezoelectric layer interposed therebetween is a resonance region where an acoustic wave is excited. It is known to use a lithium niobate layer or a lithium tantalate layer as the piezoelectric layer (for example, Patent Literature 1). It is known that the leakage of the acoustic wave is suppressed by providing through holes along the resonance region in the piezoelectric layer (for example, Non-Patent Literature 1).

### PRIOR ART LITERATURES

### Patent Literature

[Patent Literature 1] Japanese Laid-Open Patent Publication No. 2008-42871
[Non-Patent Literature 1] Ting Wu, et al., “Application of Free Side Edges to Thickness Shear Bulk Acoustic Resonator On Lithium Niobate for Suppression of Transverse Resonance”, Materials from the Second Meeting of the Acoustic wave Device Technology Consortium, Mar. 8, 2021.

### SUMMARY OF THE INVENTION

### Technical Problem

When the piezoelectric layer is etched to form the through holes along the resonance region, a part of the lower electrode may be etched. In this case, the material removed by etching of the piezoelectric layer and the lower electrode may adhere to the side surfaces of the upper electrode. When the etched material of the lower electrode is adhered to the side surfaces of the upper electrode, the lower electrode and the upper electrode may be short-circuited through the adhered film, and a device characteristic may be deteriorated.

In view of the circumstances as described above, an object of the present disclosure is to suppress short-circuit between the lower electrode and the upper electrode.

### Solution to Problem

According to a first aspect of the embodiments, there is provided an acoustic wave device including: a substrate; a lower electrode provided above the substrate; an upper electrode provided above the lower electrode; a piezoelectric layer provided above the substrate with at least a part of the piezoelectric layer interposed between the lower electrode and the upper electrode, the piezoelectric layer having a through hole along a resonance region where the lower electrode and the upper electrode overlap with each other with the at least a part of the piezoelectric layer interposed therebetween in planar view, the through hole exposing at least a part of the lower electrode; an insertion film provided either or both of between the lower electrode and the piezoelectric layer and between the upper electrode and the piezoelectric layer, the insertion film having a resistivity higher than resistivities of the lower electrode and the upper electrode; a first film in contact with, and extending upward from, a side surface of the lower electrode to a side of a side surface of the upper electrode, the first film containing a constituent element of the lower electrode; a second film in contact with, and extending upward from, a side surface of the piezoelectric layer to a region between the side surface of the upper electrode and the first film, the second film having a concentration of a constituent element of the piezoelectric layer higher than that of the first film; and a third film in contact with, and extending upward from, a side surface of the insertion film so as to extend to at least one of a region between the side surface of the upper electrode and the second film and a region between the first film and the second film, wherein a concentration of a first element of the third film, which is a constituent element of the insertion film and different from a constituent element of the piezoelectric layer, is higher than that of the second film, and a concentration of a second element of the third film, which is the constituent element of the piezoelectric layer and different from the constituent element of the insertion film, is lower than that of the second film.

In the above configuration, the second film and the third film may have a concentration of a constituent element of the lower electrode lower than that of the first film.

In the above configuration, the second film and the third film may not contain a constituent element of the lower electrode.

In the above configuration, the first film may have a concentration of the constituent element of the insertion film lower than that of the third film.

In the above configuration, the insertion film may be an inorganic insulating film.

In the above configuration, the insertion film may be formed to contain at least one of silicon oxide, silicon nitride, aluminum nitride, aluminum oxide, tantalum oxide, zirconium oxide, silicon carbide, yttrium oxide, hafnium oxide, titanium oxide, and magnesium oxide.

In the above configuration, the piezoelectric layer may be a single crystal lithium tantalate layer or a single crystal lithium niobate layer.

In the above configuration, the lower electrode and the upper electrode may excite thickness-shear vibration in the piezoelectric layer in the resonance region, two through holes may be provided with the resonance region interposed therebetween, and a vibration direction of the thickness-shear vibration may be a direction intersecting a direction in which the two through holes face each other with the resonance region interposed therebetween.

In the above configuration, a maximum distance between the through hole and the piezoelectric layer in the resonance region may be 3.2 times or less a thickness of the piezoelectric layer in the resonance region.

According to a second aspect of the embodiments, there is provided a filter including the acoustic wave device described above.

According to a third aspect of the embodiments, there is provided a multiplexer including the filter described above.

According to a fourth aspect of the embodiments, there is provided a method of manufacturing an acoustic wave device including: forming a lower electrode, a piezoelectric layer, and an upper electrode in this order on a substrate; forming an insertion film provided on at least one region between the lower electrode and the piezoelectric layer and between the piezoelectric layer and the upper electrode, the insertion film having a resistivity higher than those of the lower electrode and the upper electrode; etching the piezoelectric layer, the insertion film, and the lower electrode on a side part of a resonance region where the lower electrode and the upper electrode overlap with the piezoelectric layer interposed therebetween so as to form a through hole in the piezoelectric layer along the resonance region such that a second film adhered by etching the piezoelectric layer is formed between a first film adhered by etching the lower electrode and a side surface of the upper electrode, and such that a third film adhered by etching the insertion film is formed on at least one of a region between the side surface of the upper electrode and the second film and a region between the first film and the second film.

In the above configuration, the piezoelectric layer, the insertion film and the lower electrode may be etched by an ion milling method.

### Advantageous Effects of Invention

According to the present disclosure, it is possible to suppress short-circuit between the lower electrode and the upper electrode.

### BRIEF DESCRIPTION OF THE DRAWINGS

FIG. 1 is a plan view of an acoustic wave device according to a first embodiment;

FIG. 2A is a cross-sectional view taken along a line A-A in FIG. 1;

FIG. 2B is a cross-sectional view taken along a line B-B in FIG. 1;

FIGS. 3A and 3B are diagrams illustrating relationship between the crystal orientation of a piezoelectric layer and the vibration direction of thickness-shear vibration when the piezoelectric layer is a lithium niobate layer or a lithium tantalate layer;

FIG. 4 is a cross-sectional view of a model A used in a simulation;

FIG. 5 is a simulation result of ΔY with respect to a distance between a through hole and a resonance region in the model A;

FIGS. 6A to 6C are cross-sectional views (Part 1) illustrating a method of manufacturing the acoustic wave device according to the first embodiment;

FIGS. 7A and 7B are cross-sectional views (No. 2) illustrating a method of manufacturing the acoustic wave device according to the first embodiment;

FIG. 8 is a cross-sectional view of the vicinity of the through hole in the first embodiment;

FIGS. 9A and 9B are cross-sectional views (Part 1) illustrating a step of forming the through hole in the first embodiment;

FIGS. 10A to 10C are cross-sectional views (Part 2) illustrating a step of forming the through hole in the first embodiment;

FIG. 11 is a diagram illustrating the experimental results of composition analysis in the first embodiment;

FIG. 12 is a cross-sectional view of the vicinity of the through hole in a first modification of the first embodiment;

FIG. 13 is a cross-sectional view of the vicinity of the through hole in a second modification of the first embodiment;

FIG. 14 is a cross-sectional view of the vicinity of the through hole in a comparative example;

FIG. 15 is a diagram illustrating the experimental results of composition analysis in the comparative example;

FIGS. 16A and 16B are cross-sectional views of an acoustic wave device according to a second embodiment;

FIG. 17 is a circuit diagram of a filter according to a third embodiment; and

FIG. 18 is a circuit diagram of a duplexer according to a fourth embodiment.

### DETAILED DESCRIPTION

Hereinafter, embodiments of the present disclosure will be described with reference to the drawings.

### First Embodiment

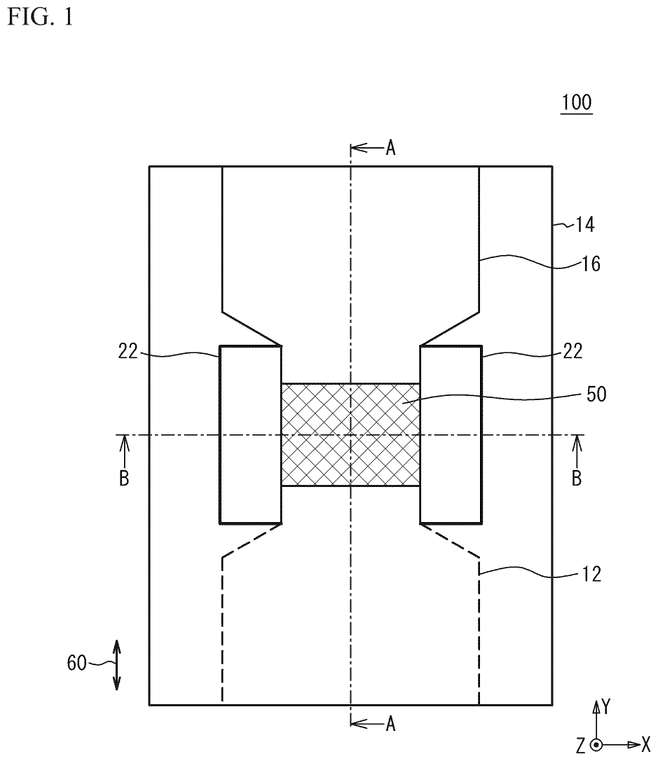

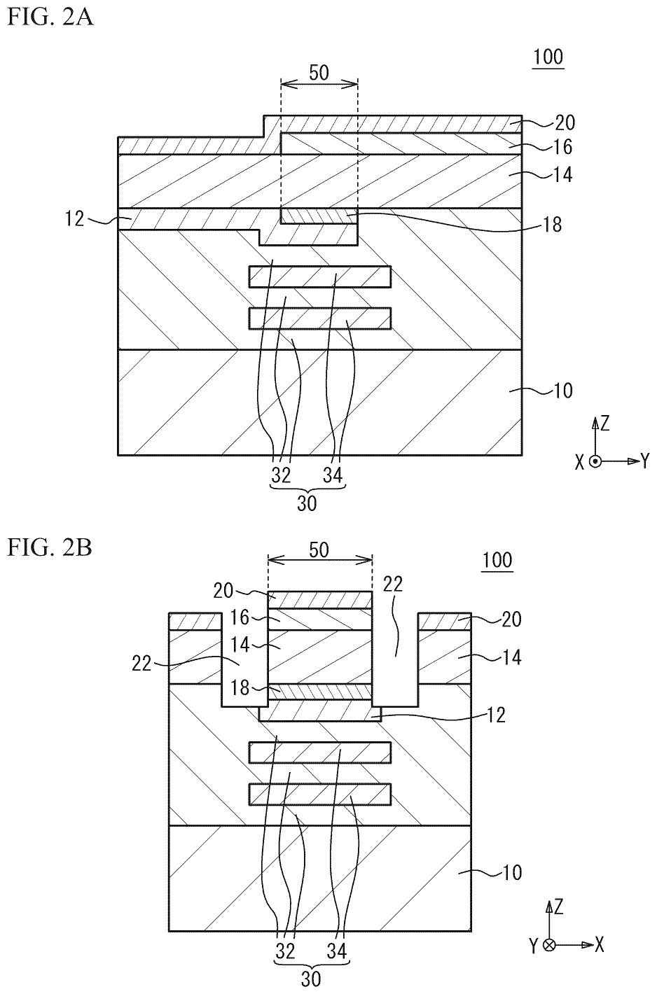

FIG. 1 is a plan view of an acoustic wave device 100 according to a first embodiment. FIG. 2A is a cross-sectional view taken along a line A-A in FIG. 1, and FIG. 2B is a cross-sectional view taken along a line B-B in FIG. 1. In FIG. 1, a lower electrode 12, a piezoelectric layer 14, and an upper electrode 16 are mainly illustrated. For the sake of clarity, in FIG. 1, a resonance region 50 is hatched, and through holes 22 are illustrated by a line thicker than lines of the other portions, and in FIG. 2B, a film formed on the side surfaces of the upper electrode 16 and the like is not illustrated. A normal direction of the piezoelectric layer 14 is defined as a Z direction, and directions orthogonal to each other in the planar direction of the piezoelectric layer 14 are defined as an X direction and a Y direction.

As illustrated in FIGS. 1, 2A, and 2B, the acoustic wave device 100 is a piezoelectric thin film resonator including the lower electrode 12, the piezoelectric layer 14, and the upper electrode 16. An acoustic reflection film 30 is provided on a substrate 10, and the piezoelectric layer 14 is provided on the acoustic reflection film 30. The upper and lower surfaces of the piezoelectric layer 14 are flat surfaces. The upper electrode 16 and the lower electrode 12 are provided on and under the piezoelectric layer 14, respectively. A region where the lower electrode 12 and the upper electrode 16 overlap with at least a part of the piezoelectric layer 14 interposed therebetween in planar view is the resonance region 50. The plane shape of the resonance region 50 is, for example, substantially rectangular. The rectangle has four sides that are approximately straight. One pair of sides of the four sides extends substantially along the Y direction, and the other pair of sides of the four sides extends substantially along the X direction.

The substrate 10 is, for example, a silicon substrate, a sapphire substrate, an alumina substrate, a spinel substrate, a quartz substrate, a quartz substrate, a glass substrate, a ceramic substrate, a GaAs substrate, or the like. The piezoelectric layer 14 is, for example, a single crystal lithium niobate layer or a single crystal lithium tantalate layer. The thickness of the piezoelectric layer 14 is, for example, about 200 nm to 1000 nm. The lower electrode 12 and the upper electrode 16 are, for example, a single layer film of ruthenium (Ru), chromium (Cr), aluminum (Al), titanium (Ti), copper (Cu), molybdenum (Mo), tungsten (W), tantalum (Ta), platinum (Pt), rhodium (Rh), or iridium (Ir) or a laminated film thereof. The thickness of each of the lower electrode 12 and the upper electrode 16 is, for example, about 20 nm to 150 nm. The lower electrode 12 and the upper electrode 16 are formed of, for example, a metal element different from the constituent element of the piezoelectric layer 14.

When a high frequency power is applied between the lower electrode 12 and the upper electrode 16, an acoustic wave is excited in the piezoelectric layer 14 in the resonance region 50. The wavelength λ of the acoustic wave is approximately twice the thickness of the piezoelectric layer 14. When the piezoelectric layer 14 is the single crystal lithium niobate layer or the single crystal lithium tantalate layer, an acoustic wave in which the displacement of the acoustic wave oscillates in a direction substantially orthogonal to the Z direction (that is, a strain direction with respect to the thickness) is excited in the piezoelectric layer 14. This vibration is called the thickness-shear vibration. A direction in which the displacement of the thickness-shear vibration is maximum (i.e., a displacement direction of the thickness-shear vibration) is defined as a vibration direction 60 of the thickness-shear vibration. In this case, the vibration direction 60 of the thickness-shear vibration is the Y direction. The lower electrode 12 and the upper electrode 16 are drawn out from the resonance region 50 in the Y direction, which is the same as the vibration direction 60 of the thickness-shear vibration.

The acoustic reflection film 30 includes films 32 having a low acoustic impedance and films 34 having a high acoustic impedance. The films 32 having the low acoustic impedance and the films 34 having the high acoustic impedance are alternately provided in the resonance region 50. The thicknesses of the films 32 and 34 in the resonance region 50 are, for example, substantially λ/4 (λ is the wavelength of the acoustic wave). Thus, the acoustic reflection film 30 reflects the acoustic wave. The number of layers of the films 32 and 34 can be set freely. The acoustic reflection film 30 may be formed by laminating at least two kinds of layers having different acoustic characteristics with a space therebetween. The substrate 10 may be formed of at least one layer of two kinds of layers having different acoustic characteristics of the acoustic reflection film 30. For example, the acoustic reflection film 30 may be formed by providing a single layer of films having different acoustic impedances in the substrate 10. In planar view, a laminated portion of the film 32 and the film 34 overlaps with the resonance region 50 and has the same size as the resonance region 50 or is larger than the resonance region 50. By making the laminated portion of the film 32 and the film 34 larger than the resonance region 50 in planar view, the acoustic wave leaking from the resonance region 50 in an oblique direction can be reflected by the acoustic reflection film 30, and deterioration of the characteristics can be suppressed. The film 32 having the low acoustic impedance is, for example, a silicon oxide (SiO₂) film, and the film 34 having the high acoustic impedance is, for example, a tungsten (W) film.

An insertion film 18 is provided between the lower electrode 12 and the piezoelectric layer 14 in the resonance region 50. The insertion film 18 has the same size as the resonance region 50 or is larger than the resonance region 50 in planar view. The insertion film 18 is a film having a volume resistivity higher than those of the lower electrode 12 and the upper electrode 16, and is, for example, a silicon oxide (SiO₂) film. The thickness of the insertion film 18 is, for example, about 5 nm to 20 nm, and is, for example, 10% or less of the thickness of the piezoelectric layer 14. A protective film 20 is provided to cover the piezoelectric layer 14 and the upper electrode 16. The protective film 20 is an insulating film, and is, for example, a silicon oxide (SiO₂) film, a silicon nitride (SiN) film, an aluminum oxide (Al₂O₃) film, or the like.

The piezoelectric layer 14 is formed with a pair of through holes 22 that interpose the resonance region 50 in the X direction and extend along the resonance region 50 in the Y direction. The through hole 22 is dug to a part of the lower electrode 12. A distance between one of the pair of through holes 22 and the piezoelectric layer 14 in the resonance region 50 is substantially the same as a distance between the other of the pair of through holes 22 and the piezoelectric layer 14 in the resonance region 50. The through hole 22 has a substantially rectangular shape in planar view, for example. The through hole 22 prevents the acoustic wave excited in the resonance region 50 from leaking to the outside.

Here, a description will be given of the relationship between the crystal orientation of the piezoelectric layer 14 and the vibration direction 60 of the thickness-shear vibration in the case where the piezoelectric layer 14 is the lithium niobate layer or the lithium tantalate layer. First, the definition of Euler angles (φ, θ, ψ) will be described. In a right-handed XYZ coordinate system, a normal direction of the upper surface of the piezoelectric layer 14 is defined as the Z direction, and directions orthogonal to the Z direction and orthogonal to each other in the surface direction of the upper surface of the piezoelectric layer 14 are defined as the X direction and the Y direction. The X direction, the Y direction, and the Z direction are defined as an X axis direction, a Y axis direction, and a Z axis direction of the crystal orientation, respectively. Next, the XYZ coordinate system is rotated by an angle φ from the +X direction to the +Y direction around the Z direction. The XYZ coordinate system is rotated by an angle θ from the +Y direction to the +Z direction around the X direction after the angle φ rotation. The XYZ coordinate system is rotated by an angle ψ from the +X direction to the +Y direction around the Z direction after the angle θ rotation. The Euler angles obtained by such rotation are defined as (φ, θ, ψ). The Euler angles expressed using (φ, θ, ψ) include equivalent Euler angles.

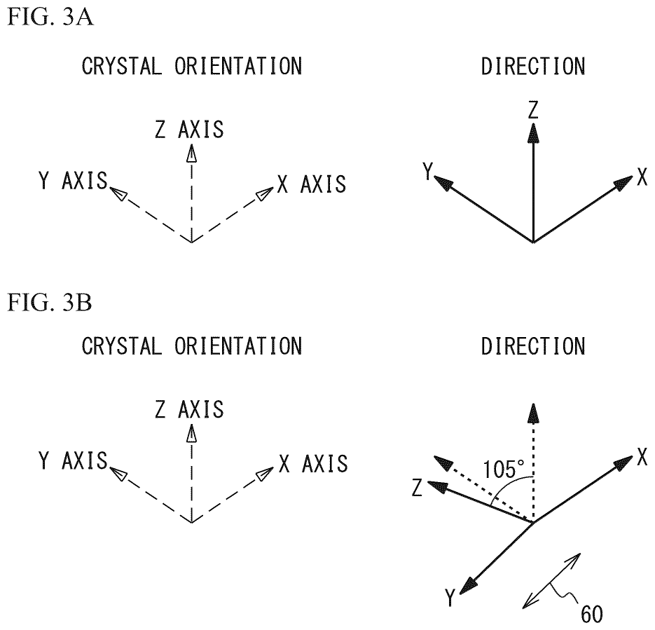

FIGS. 3A and 3B are diagrams illustrating the relationship between the crystal orientation of the piezoelectric layer 14 and the vibration direction 60 of the thickness-shear vibration when the piezoelectric layer 14 is the lithium niobate layer or the lithium tantalate layer. The broken line arrows on the left side in FIGS. 3A and 3B indicate the orientation of the crystal axes of the piezoelectric layer 14. The solid line arrows on the right side correspond to the X direction, the Y direction, and the Z direction in FIGS. 1, 2A, and 2B. As illustrated in FIG. 3A, the +X direction, the +Y direction, and the +Z direction are defined as the +X axis direction, the +Y axis direction, and the +Z axis direction of the crystal orientation of the piezoelectric layer 14, respectively. As illustrated in FIG. 3B, the +Y direction and the +Z direction are rotated by 105° from the +Y direction to the −Z direction on the YZ plane around the X direction from the state of FIG. 3A. When the +Y direction and the +Z direction are rotated in this way, a direction in which the +Z axis direction of the crystal orientation is rotated by 105° toward the +Y axis direction is the +Z direction. At this time, the Y direction is the vibration direction 60 of the thickness-shear vibration. The Euler angles are (0°, ˜105°, 0°). When the Euler angles derived by the same method as described above are (0°, −105°, 90°), the X direction is the vibration direction 60 of the thickness-shear vibration. Each angle of the Euler angles is allowed to be within a range of ±5°, and is more preferably within a range of ±1°.

### [Simulation]

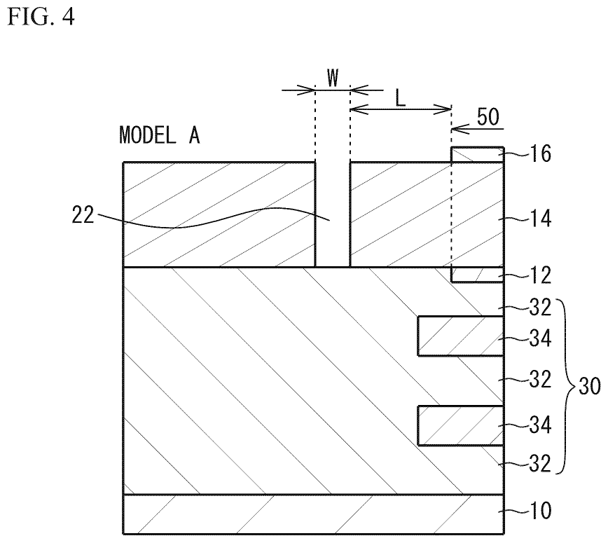

FIG. 4 is a cross-sectional view of a model A used in simulation. As illustrated in FIG. 4, the model A includes the acoustic reflection film 30 having the films 32 having the low acoustic impedance and the films 34 having the high acoustic impedance on the substrate 10. The piezoelectric layer 14 is provided on the acoustic reflection film 30. The lower electrode 12 and the upper electrode 16 are provided so as to interpose the piezoelectric layer 14 therebetween. Thus, the resonance region 50 is formed. The through holes 22 positioned on the side parts of the resonance region 50 are provided in the piezoelectric layer 14.

The model A was simulated with respect to ΔY when a distance L between the through hole 22 and the resonance region 50 varies. The ΔY was calculated by obtaining a difference between an absolute value of an admittance Y at a resonance frequency and an absolute value of the admittance Y at an anti-resonance frequency from a simulation result of a frequency characteristic of the admittance Y The simulation conditions are as follows.

### Substrate 10: Silicon Substrate

Film 32 having low acoustic impedance: Silicon oxide (SiO₂) film having thickness of 150 nm in resonance region 50
Film 34 having high acoustic impedance: Tungsten (W) film having thickness of 115 nm in resonance region 50
Lower electrode 12: Aluminum (Al) film having thickness of 44 nm
Piezoelectric layer 14: Single crystal lithium niobate (LiNbO₃) layer having thickness of 310 nm
Upper electrode 16: Aluminum (Al) film having thickness of 44 nm
Width W of through hole 22: 1.0 μm
Wavelength of acoustic wave: 620 nm

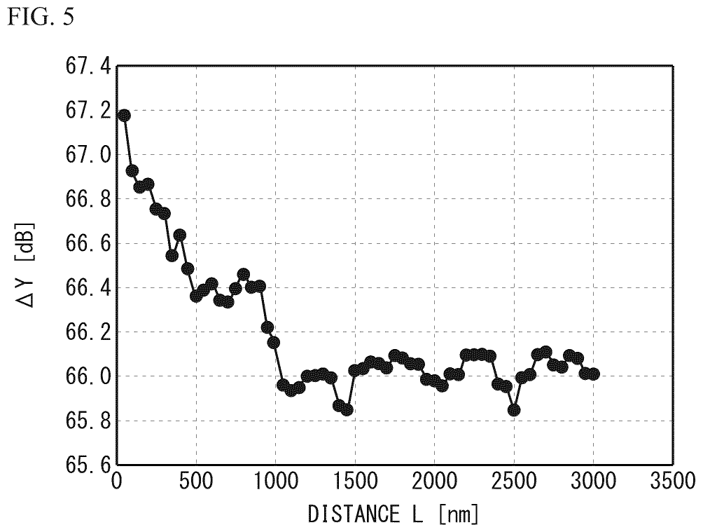

FIG. 5 illustrates a simulation result of the ΔY with respect to the distance L between the through hole 22 and the resonance region 50 in the model A. As illustrated in FIG. 5, the ΔY decreases as the distance L increases up to the distance L of about 1000 nm. When the distance L exceeded 1000 nm, the decrease in ΔY was saturated and the ΔY was almost the same value and constant. From this result, the through hole 22 is preferably formed at a position where the distance L from the resonance region 50 is 1.0 μm or less from the viewpoint of suppressing the increase in size of the device while suppressing the deterioration of the device characteristics. In other words, the through hole 22 is preferably formed at a position where the distance L from the resonance region 50 is 1.6λ or less.

### [Manufacturing Method]

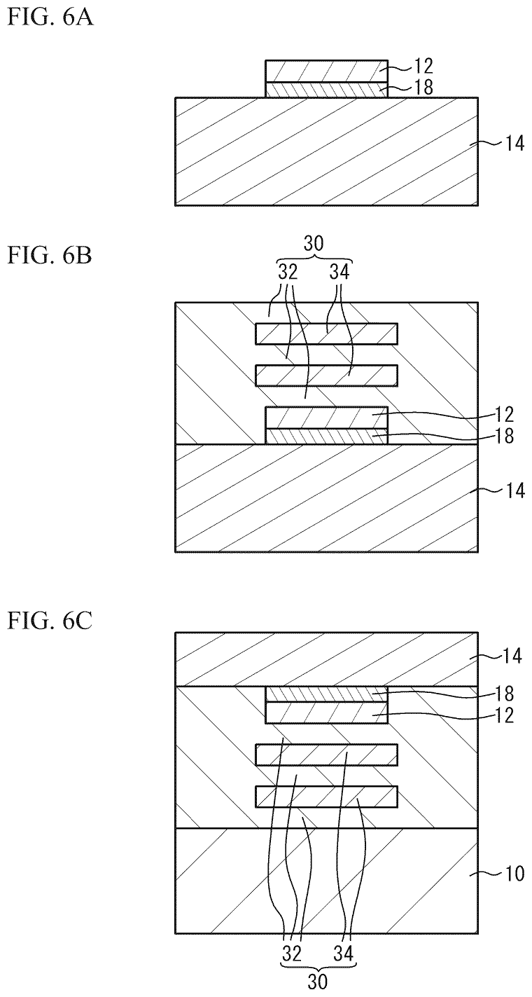

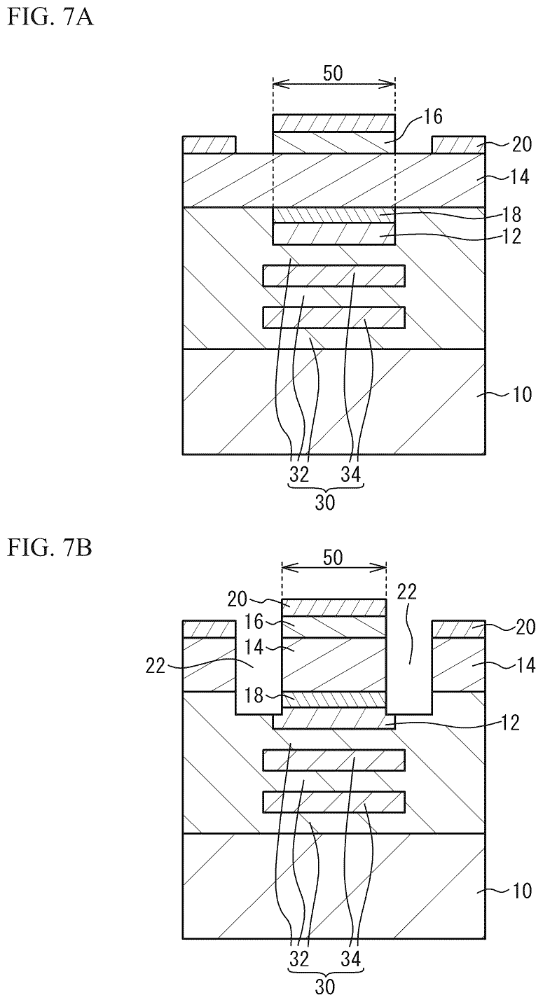

FIGS. 6A to 7B are cross-sectional views illustrating a method of manufacturing the acoustic wave device 100 according to the first embodiment. FIGS. 6A to 7B are cross-sectional views of a portion corresponding to the line B-B in FIG. 1. As illustrated in FIG. 6A, a piezoelectric substrate is prepared as the piezoelectric layer 14. The insertion film 18 and the lower electrode 12 are formed on the piezoelectric layer 14. The insertion film 18 and the lower electrode 12 are formed by, for example, a sputtering method, a vacuum evaporation method, or a CVD (Chemical Vapor Deposition) method, and then they are patterned into a desired shape by, for example, a photolithography method and an etching method. The insertion film 18 and the lower electrode 12 may be formed by a lift-off method.

As illustrated in FIG. 6B, the acoustic reflection film 30 is formed on the piezoelectric layer 14 to cover the insertion film 18 and the lower electrode 12. The acoustic reflection film 30 is formed by alternately forming the films 32 having the low acoustic impedance and the films 34 having the high acoustic impedance, and patterning the films 34 having the high acoustic impedance into the desired shape. The films 32 having the low acoustic impedance and the films 34 having the high acoustic impedance are formed by, for example, the sputtering method or the CVD method, and patterned by, for example, the photolithography method and the etching method. Then, the upper surface of the acoustic reflection film 30 is planarized by, for example, a CMP (Chemical Mechanical Polishing) method.

As illustrated in FIG. 6C, the acoustic reflection film 30 is bonded to the substrate 10. For example, a surface activation method is used for the bonding. A bonding layer such as a silicon film may be provided between the substrate 10 and the acoustic reflection film 30. Next, the piezoelectric layer 14 is thinned to a desired thickness. For example, a grinding method and/or the CMP method is used for the film thinning. For example, the piezoelectric layer 14 is made to have a substantially desired thickness by using the grinding method, and the upper surface is planarized by using the CMP method. This makes the upper surface of the piezoelectric layer 14 flat to the degree of manufacturing error.

As illustrated in FIG. 7A, the upper electrode 16 and the protective film 20 are formed on the piezoelectric layer 14. The upper electrode 16 and the protective film 20 are formed by depositing a film using, for example, the sputtering method, the vacuum evaporation method, or the CVD method, and then patterning the film into the desired shape using, for example, the photolithography method and the etching method. The upper electrode 16 may be formed by the lift-off method. The resonance region 50 is formed in which the lower electrode 12 and the upper electrode 16 overlap with the at least a part of the piezoelectric layer 14 interposed therebetween in planar view.

As illustrated in FIG. 7B, the piezoelectric layer 14 on the side parts of the resonance region 50 is removed, and the through holes 22 along the resonance region 50 are formed in the piezoelectric layer 14. The piezoelectric layer 14 is removed by the photolithography method and the etching method, for example. For example, the piezoelectric layer 14 is removed by the dry etching method, for example, by an ion milling method using argon (Ar) gas. At this time, the over-etching is performed so that the through holes 22 penetrating the piezoelectric layer 14 are surely formed. Therefore, the insertion film 18 and the lower electrode 12 are also etched. The above process completes the formation of the acoustic wave device 100 according to the first embodiment.

### [Vicinity of Through Hole]

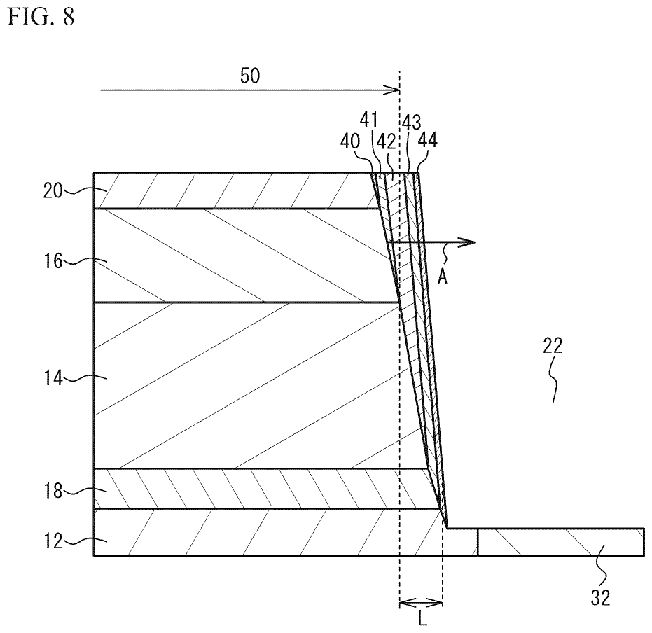

FIG. 8 is a cross-sectional view of the vicinity of the through hole 22 in the first embodiment. As illustrated in FIG. 8, a film 40 containing the material of the protective film 20 is formed on the side surface of the protective film 20. A film 41 containing the material of the upper electrode 16 is formed from the side surface of the upper electrode 16 to the side surface of the film 40. A film 42 containing the material of the piezoelectric layer 14 is formed from the side surface of the piezoelectric layer 14 to the side surface of the film 41. A film 43 containing the material of the insertion film 18 is formed from the side surface of the insertion film 18 to the side surface of the film 42. A film 44 containing the material of the lower electrode 12 is formed from the side surface of the lower electrode 12 to the side surface of the film 43. Since the films 40, 41, 42, 43 and 44 are adhesion films adhered when the through holes 22 are formed, they do not take a regular crystal structure state, that is, they contain a large proportion of amorphous.

A maximum distance L between the through hole 22 and the piezoelectric layer 14 in the resonance region 50 is 1.0 μm or less. As a result, as illustrated in FIG. 5, it is possible to suppress the increase in size of the device while suppressing the deterioration of the device characteristics. From the viewpoint of suppressing the deterioration of the device characteristics, the distance L is preferably 0.8 μm or less, more preferably 0.5 μm or less, and still more preferably 0.2 μm or less.

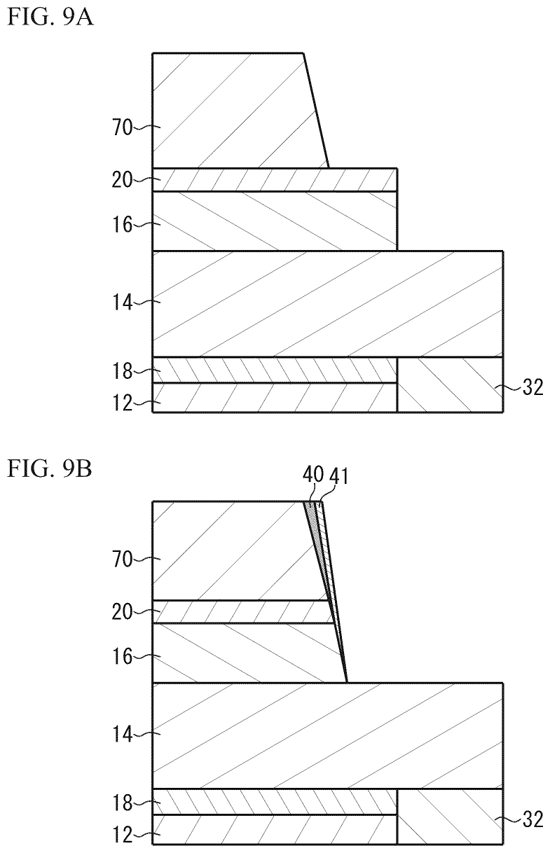

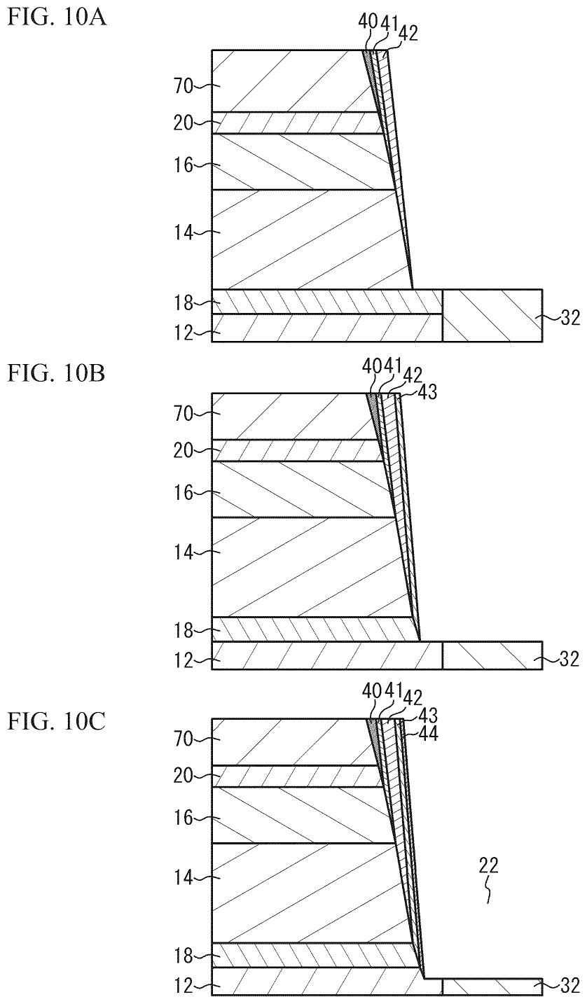

The process of forming the films 40, 41, 42, 43 and 44 will be described with reference to the drawings. FIGS. 9A to 10C. are cross-sectional views illustrating a step of forming the through hole 22 in the first embodiment. As illustrated in FIG. 9A, a mask layer 70 made of a photoresist is formed on the upper electrode 16. The mask layer 70 is formed at a position inside the edge of the upper electrode 16.

As illustrated in FIG. 9B, the protective film 20 and the upper electrode 16 are etched using the mask layer 70 as a mask. The etching is performed by the dry etching method, for example, the ion milling method using Ar gas. The material removed during the etching of the protective film 20 is adhered to the side surface of the protective film 20 and the side surface of the mask layer 70, and the film 40 containing the material of the protective film 20 is formed from the side surface of the protective film 20 to the side surface of the mask layer 70. The material removed during the etching of the upper electrode 16 is adhered to the side surfaces of the upper electrode 16 and the film 40, and the film 41 containing the material of the upper electrode 16 is formed from the side surface of the upper electrode 16 to the side surface of the film 40.

As illustrated in FIG. 10A, after the protective film 20 and the upper electrode 16 are etched, the piezoelectric layer 14 is etched using the mask layer 70 as a mask. As described above, the etching is performed by the dry etching method, for example, the ion milling method using Ar gas. The material removed during the etching of the piezoelectric layer 14 is adhered to the side surface of the piezoelectric layer 14 and the side surface of the film 41, and the film 42 containing the material of the piezoelectric layer 14 is formed from the side surface of the piezoelectric layer 14 to the side surface of the film 41.

As illustrated in FIG. 10B, after the piezoelectric layer 14 is etched, the insertion film 18 is etched using the mask layer 70 as a mask. As described above, the etching is performed by the dry etching method, for example, the ion milling method using Ar gas. The material removed during etching of the insertion film 18 is adhered to the side surface of the insertion film 18 and the side surface of the film 42, and the film 43 containing the material of the insertion film 18 is formed from the side surface of the insertion film 18 to the side surface of the film 42.

As illustrated in FIG. 10C, after the insertion film 18 is etched, the lower electrode 12 is etched using the mask layer 70 as a mask. A reason why the etching is performed up to the lower electrode 12 is that the device characteristics are deteriorated when the through hole 22 does not penetrate through the piezoelectric layer 14, and therefore the overetching is performed so that the through hole 22 surely penetrates through the piezoelectric layer 14. As described above, the etching is performed by the dry etching method, for example, the ion milling method using Ar gas. The material removed during the etching of the lower electrode 12 is adhered to the side surface of the lower electrode 12 and the side surface of the film 43, and the film 44 containing the material of the lower electrode 12 is formed from the side surface of the lower electrode 12 to the side surface of the film 43.

### [Experiment]

In the first embodiment, the film 32 having the low acoustic impedance, the lower electrode 12, the insertion film 18, the piezoelectric layer 14, the upper electrode 16, and the protective film 20 were formed of the following materials and with the following film thicknesses, and the through holes 22 were formed by the ion milling method using Ar gas. The lower electrode 12 was etched by about 22 nm by over-etching when the through holes 22 were formed.
Film 32 having low acoustic impedance: Silicon oxide film
Lower electrode 12: Aluminum film having thickness of 44 nm
Insertion film 18: Silicon oxide film having thickness of 20 nm
Piezoelectric layer 14: Lithium niobate layer having thickness of 310 nm
Upper electrode 16: Aluminum film having thickness of 44 nm
Protective film 20: Silicon oxide film having thickness of 20 nm

At this time, the composition analysis of the films 41, 42, 43, and 44 was performed at a position indicated by an arrow A in FIG. 8. The composition analysis was performed by an energy dispersive X-ray spectroscopy method (EDX).

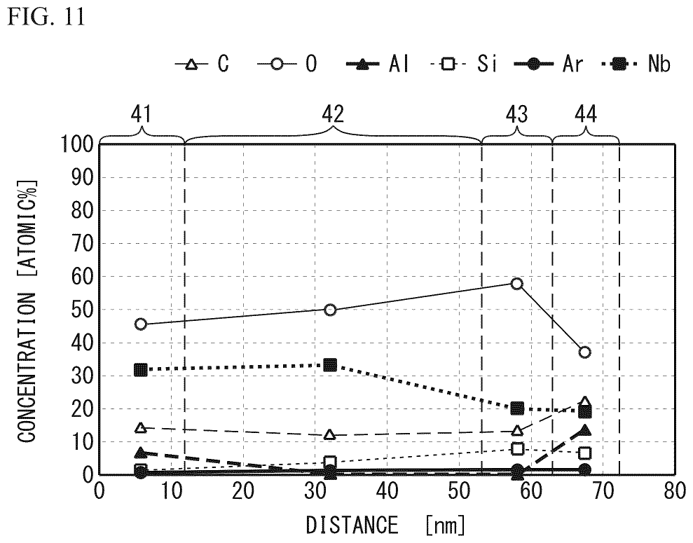

FIG. 11 is a diagram illustrating the experimental results of the composition analysis in the first embodiment. In FIG. 11, a horizontal axis represents a distance from the side surface of the upper electrode 16 in the direction of the arrow A when the position of the side surface of the upper electrode 16 is set to an original point 0, and a vertical axis represents a concentration. Table 1 illustrates the experimental results of the composition analysis in the first embodiment.

TABLE 1

| | C | O | Al | Si | Ar | Nb | total |
|---|---|---|---|---|---|---|---|
| FILM 41 | 14.19 | 45.69 | 6.39 | 1.15 | 0.65 | 31.93 | 100 |
| FILM 42 | 11.93 | 50.05 | 0 | 3.67 | 1.08 | 33.27 | 100 |
| FILM 43 | 13 | 58 | 0 | 7.7 | 1.3 | 20 | 100 |
| FILM 44 | 22.07 | 37.31 | 13.51 | 6.5 | 1.39 | 19.22 | 100 |

UNIT: ATOMIC %

As illustrated in FIG. 11 and Table 1, the film 41 contains aluminum (Al). From this, it is understood that the film 41 is formed by the adhesion of the material removed during the etching of the upper electrode 16. Carbon (C) is considered to be carbon taken in by the etching of the mask layer 70 made of the photoresist. Oxygen (O) is considered to have been introduced from oxygen contained in the films 40 and 42, which contain materials removed during etching of the protective film 20 and the piezoelectric layer 14. Silicon (Si) is considered to have been introduced from silicon contained in the film 40. Argon (Ar) is considered to be gas used in the ion milling method. Niobium (Nb) is considered to have been introduced from niobium contained in the film 42.

The film 42 does not contain aluminum, and has a niobium concentration higher than those of the other films 41, 43, and 44 and a silicon concentration lower than that of the film 43. For example, the concentration of niobium in the film 42 is 1.3 times or more and 1.5 times or more that of niobium in the film 44. From this, it is understood that the film 42 is formed by the adhesion of the material removed during the etching of the piezoelectric layer 14. Carbon is considered to be carbon taken in by the etching of the mask layer 70. It is considered that the oxygen concentration is high because oxygen, which is the constituent element of the piezoelectric layer 14, is taken in when the piezoelectric layer 14 is etched. Silicon is considered to have been introduced from silicon contained in the film 43. Argon gas is considered to be gas used in the ion milling method. It is considered that a reason why the film 42 does not contain lithium (Li), which is the constituent element of the piezoelectric layer 14, is that lithium is light and difficult to be taken in.

The film 43 does not contain aluminum, and has a silicon concentration higher than those of the other films 41, 42, and 44 and a niobium concentration lower than that of the film 42. For example, the silicon concentration of the film 43 is 1.8 times or more and 2.0 times or more the silicon concentration of the film 42. The concentration of niobium in the film 43 is 0.8 times or less and 0.7 times or less of the concentration of niobium in the film 42. From this, it is understood that the film 43 is formed by the adhesion of the material removed during the etching of the insertion film 18. Carbon is considered to be carbon taken in by the etching of the mask layer 70. It is considered that the oxygen concentration is high because oxygen, which is the constituent element of the insertion film 18, is taken in when the insertion film 18 is etched. Argon is considered to be gas used in the ion milling method. Niobium is considered to have been introduced from niobium contained in the film 42.

The film 44 contains aluminum. From this, it is understood that the film 44 is formed by the adhesion of the material removed during the etching of the lower electrode 12. Carbon is considered to be carbon taken in by the etching of the mask layer 70. It is considered that oxygen and silicon are taken in by etching the film 32 having the low acoustic impedance, and that oxygen contained in the film 43 is introduced. Argon is considered to be gas used in the ion milling method. Niobium is considered to have been introduced from niobium contained in the films 42 and 43.

The thicknesses of the films 41, 42, 43, and 44 correspond to the amounts of etching of the upper electrode 16, the piezoelectric layer 14, the insertion film 18, and the lower electrode 12, for example. When the piezoelectric layer 14 is thicker than the upper electrode 16, the insertion film 18, and the lower electrode 12, for example, the film 42 is thicker than the films 41, 43, and 44. When the thickness of the upper electrode 16 is larger than the thickness of the insertion film 18 and the amount of etching of the lower electrode 12, the film 41 is thicker than the films 43 and 44. When the thickness of the insertion film 18 and the amount of etching of the lower electrode 12 are substantially the same as each other, the thicknesses of the films 43 and 44 are substantially the same as each other.

### Modified Example

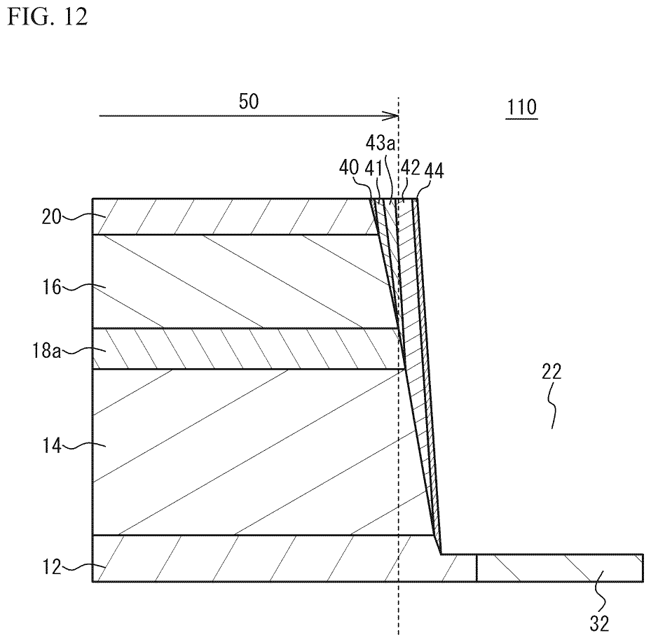

FIG. 12 is a cross-sectional view of the vicinity of the through hole 22 in a first modification of the first embodiment. As illustrated in FIG. 12, in an acoustic wave device 110 according to the first modification of the first embodiment, the insertion film 18 is not provided between the lower electrode 12 and the piezoelectric layer 14 in the resonance region 50, but alternatively, an insertion film 18a is provided between the piezoelectric layer 14 and the upper electrode 16. The insertion film 18a has the same size as the resonance region 50 or is larger than the resonance region 50 in planar view. Therefore, a film 43a containing the material of the insertion film 18a is formed from the side surface of the insertion film 18a to the side surface of the film 41. The film 42 containing the material of the piezoelectric layer 14 is formed from the side surface of the piezoelectric layer 14 to the side surface of the film 43a. The other components of the first modification of the first embodiment are the same as those of the first embodiment, and therefore, the description thereof is omitted.

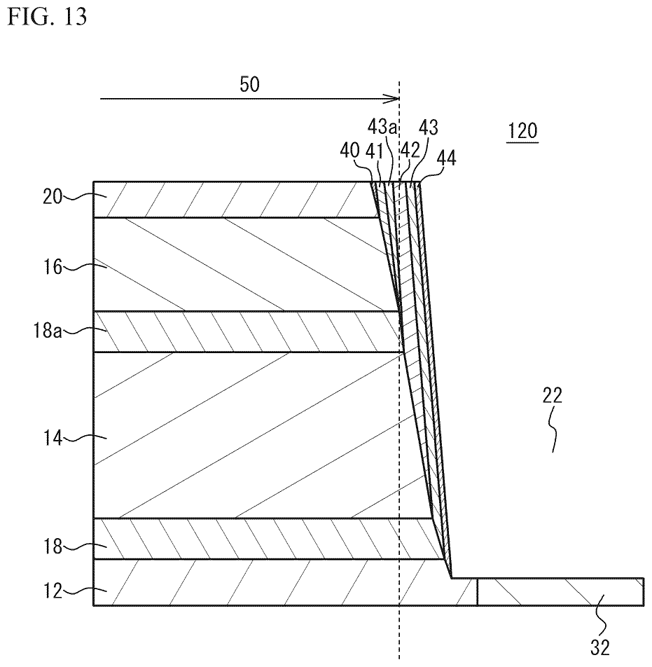

FIG. 13 is a cross-sectional view of the vicinity of the through hole 22 in a second modification of the first embodiment. As illustrated in FIG. 13, in an acoustic wave device 120 according to the second modification of the first embodiment, in addition to the insertion film 18 provided between the lower electrode 12 and the piezoelectric layer 14, the insertion film 18a is provided between the piezoelectric layer 14 and the upper electrode 16 in the resonance region 50. Therefore, the film 43a containing the material of the insertion film 18a is formed from the side surface of the insertion film 18a to the side surface of the film 41. The film 42 containing the material of the piezoelectric layer 14 is formed from the side surface of the piezoelectric layer 14 to the side surface of the film 43a. The other components of the second modification of the first embodiment are the same as those of the first embodiment, and therefore, the description thereof is omitted.

### Comparative Example

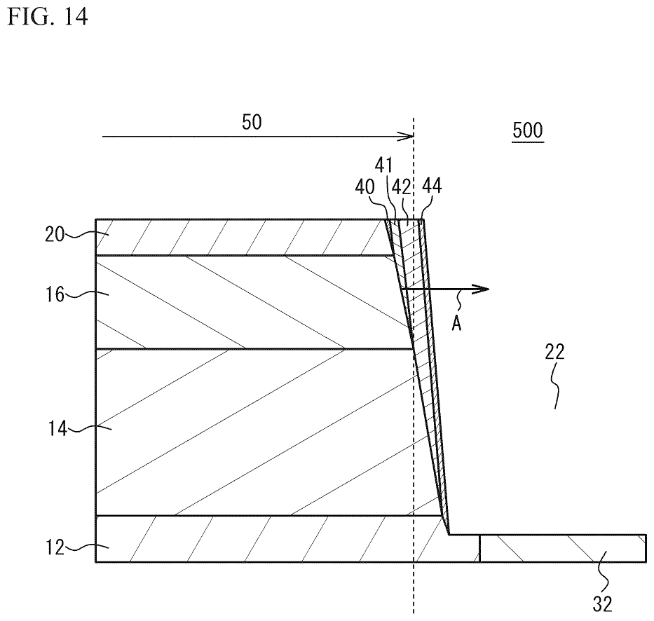

FIG. 14 is a cross-sectional view of the vicinity of the through hole 22 in a comparative example. As illustrated in FIG. 14, in an acoustic wave device 500 according to the comparative example, the insertion film 18 is not provided between the lower electrode 12 and the piezoelectric layer 14. For this reason, the film 44 containing the material of the lower electrode 12 is formed from the side surface of the lower electrode 12 to the side surface of the film 42 in contact with the film 42 containing the material of the piezoelectric layer 14 formed from the side surface of the piezoelectric layer 14 to the side surface of the film 41. That is, the film 43 containing the material of the insertion film 18 is not formed between the film 42 and the film 44. The other components of the comparative example are the same as those of the first embodiment, and therefore, the description thereof is omitted.

### [Experiment]

In the comparative example, the film 32 having the low acoustic impedance, the lower electrode 12, the piezoelectric layer 14, the upper electrode 16, and the protective film 20 were formed of the following materials and with the following film thicknesses, and the through holes 22 were formed by the ion milling method using Ar gas. The lower electrode 12 was etched by about 22 nm by over-etching when the through hole 22 was formed.
Film 32 having low acoustic impedance: Silicon oxide film
Lower electrode 12: Aluminum film having thickness of 44 nm
Piezoelectric layer 14: Lithium niobate layer having thickness of 310 nm
Upper electrode 16: Aluminum film having thickness of 44 nm
Protective film 20: Silicon oxide film having thickness of 20 nm

At this time, the composition analysis of the films 41, 42, and 44 at a position indicated by an arrow A in FIG. 14 was performed. The composition analysis was performed by the energy dispersive X-ray spectroscopy method (EDX).

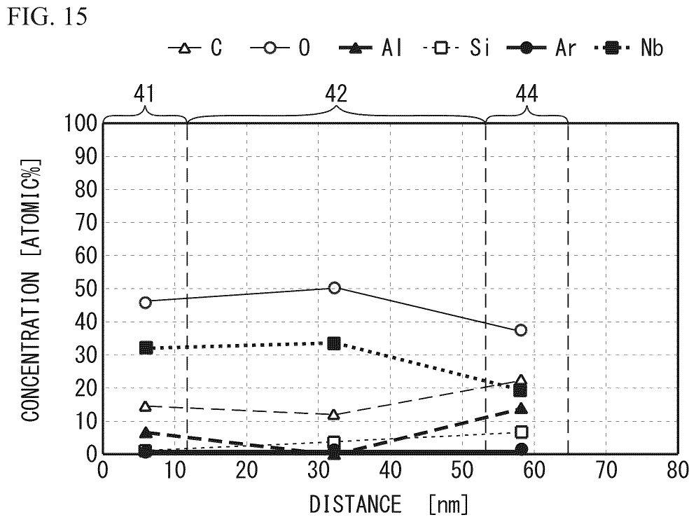

FIG. 15 is a diagram illustrating the experimental results of the composition analysis in the comparative example. In FIG. 15, a horizontal axis represents a distance from the side surface of the upper electrode 16 in the direction of the arrow A when the position of the side surface of the upper electrode 16 is set to an origin point 0, and a vertical axis represents a concentration. Table 2 illustrates the experimental results of the composition analysis in the comparative example.

TABLE 2

| | C | O | Al | Si | Ar | Nb | total |
|---|---|---|---|---|---|---|---|
| FILM 41 | 14.19 | 45.69 | 6.39 | 1.15 | 0.65 | 31.93 | 100 |
| FILM 42 | 11.93 | 50.05 | 0 | 3.67 | 1.08 | 33.27 | 100 |
| FILM 44 | 22.07 | 37.31 | 13.51 | 6.5 | 1.39 | 19.22 | 100 |

UNIT: ATOMIC %

As illustrated in FIG. 15 and Table 2, the film 41 contains aluminum. From this, it is understood that the film 41 is formed by the adhesion of the material removed during the etching of the upper electrode 16. The film 42 does not contain aluminum and has a concentration of niobium higher than those of the films 41 and 44. From this, it is understood that the film 42 is formed by the adhesion of the material removed during the etching of the piezoelectric layer 14. The film 44 includes aluminum. From this, it is understood that the film 44 is formed by the adhesion of the material removed during the etching of the lower electrode 12.

In the comparative example, as illustrated in FIG. 14, the film 44 is provided in contact with the film 42. Since the film 41 is formed by the adhesion of the material removed during the etching of the upper electrode 16, the film 41 has conductivity. Since the film 44 is formed by the adhesion of the material removed during the etching of the lower electrode 12, the film 44 has conductivity. Although the film 42 is formed by the adhesion of the material removed during the etching of the piezoelectric layer 14, the film 42 has a low insulation property because it is amorphous and has a poor film quality. Therefore, the film 41 and the film 44 are electrically connected at a thin portion of the film 42, and the lower electrode 12 and the upper electrode 16 may be short-circuited through the films 41, 42, and 44. The short-circuit deteriorates the device characteristics. Although the insulation property is increased as the thickness of the film 42 is increased, it is difficult to increase the thickness of the film 42 because the film 42 corresponds to the thickness of the piezoelectric layer 14 and the thickness of the piezoelectric layer 14 is determined by the wavelength of the desired acoustic wave.

On the other hand, in the first embodiment and the modifications thereof, as illustrated in FIGS. 8, 12, and 13, at least one of the insertion films 18 and 18a having resistivities higher than those of the lower electrode 12 and the upper electrode 16 is provided between at least one of the lower electrode 12 and the upper electrode 16, and the piezoelectric layer 14. For this reason, at least one of the films 43 and 43a, which are films to which the materials removed during the etching of the insertion films 18 and 18a are adhered, is formed on at least one region between the films 44 and 42 and between the side surface of the upper electrode 16 and the film 42 Since the film 44 (first film) is a film to which the material removed during the etching of the lower electrode 12 is adhered, the film 44 is connected to the lower electrode 12 and contains Al, which is the constituent element of the lower electrode 12, as illustrated in FIG. 11 and Table 1. Since the film 42 (second film) is a film to which the material removed during the etching of the piezoelectric layer 14 is adhered, the concentration of Nb, which is the constituent element of the piezoelectric layer 14, is higher than that of the film 44. Since the films 43 and 43a (third film) are films to which the materials removed during the etching of the insertion films 18 and 18a are adhered, the concentration of Si, which is the constituent element of the insertion films 18 and 18a and is not the constituent element of the piezoelectric layer 14, is higher than that of the film 42, and the concentration of Nb, which is the constituent element of the piezoelectric layer 14 and is not the constituent element of the insertion films 18 and 18a, is lower than that of the film 42. Since the films 43 and 43a are films to which the materials removed during etching of the insertion films 18 and 18a, which have resistivities higher than those of the lower electrode 12 and the upper electrode 16, are adhered, the films 43 and 43a have insulation properties higher than those of the film 41 as the film to which the material removed during etching of the upper electrode 16 is adhered and the film 44 as the film to which the material removed during etching of the lower electrode 12 is adhered. Therefore, by providing at least one of the film 43 and the film 43a between the film 41 and the film 44, the electrical connection between the film 41 and the film 44 is suppressed. Therefore, the short-circuit between the lower electrode 12 and the upper electrode 16 can be suppressed.

In the manufacturing method of the first embodiment and the modifications thereof, as illustrated in FIG. 7A, the lower electrode 12, the piezoelectric layer 14, and the upper electrode 16 are formed in this order on the substrate 10, and at least one of the insertion films 18 and 18a is formed on at least one region between the lower electrode 12 and the piezoelectric layer 14 and between the piezoelectric layer 14 and the upper electrode 16 (see also FIGS. 12 and 13). As illustrated in FIGS. 7B and 9A to 10C, the piezoelectric layer 14, the insertion films 18 and 18a, and the lower electrode 12 on the side parts of the resonance region 50 are etched to form the through hole 22 in the piezoelectric layer 14. At this time, the film 42 (second film) adhered by etching the piezoelectric layer 14 is formed between the film 44 (first film) adhered by etching the lower electrode 12 and the side surface of the upper electrode 16, and at least one of the films 43 and 43a (third film) adhered by etching the insertion films 18 and 18a is formed on at least one region between the side surface of the upper electrode 16 and the film 42 and between the film 44 and the film 42 (see also FIGS. 12 and 13). Thus, at least one of the films 43 and 43a is provided between the film 41 and the film 44, so that the electrical connection between the film 41 and the film 44 is suppressed, and the short-circuit between the lower electrode 12 and the upper electrode 16 can be suppressed.

In the first embodiment and the modifications thereof, the ion milling method is used for etching the piezoelectric layer 14, the insertion films 18 and 18a, and the lower electrode 12. This makes it possible to form the through hole 22 in the piezoelectric layer 14 regardless of the type of the piezoelectric layer 14. When the ion milling method is used, the material removed during the etching is likely to adhere to the side surfaces of the upper electrode 16 to form an adhesion film. In this case, as in the comparative example, when the insertion films 18 and 18a are not provided, the short-circuit may occur between the lower electrode 12 and the upper electrode 16. Accordingly, when the ion milling method is used, it is preferable to form at least one of the insertion films 18 and 18a on at least one region between the lower electrode 12 and the piezoelectric layer 14 and between the piezoelectric layer 14 and the upper electrode 16.

In the first embodiment and the modifications thereof, since the film 42 is the film to which the material removed during the etching of the piezoelectric layer 14 is adhered, the concentration of Al, which is the constituent element of the lower electrode 12, is lower than that of the film 44, and the film 42 does not contain Al, for example, as illustrated in FIG. 11 and Table 1. Since the films 43 and 43a are films to which the materials removed during the etching of the insertion films 18 and 18a are adhered, the concentration of Al, which is the constituent element of the lower electrode 12, is lower than that of the film 44, and the films 43 and 43a do not contain Al, for example. This suppresses the electrical connection between the films 41 and 44, and can suppress the short-circuit between the lower electrode 12 and the upper electrode 16. The concentration of Al in the films 42 and 43 is preferably 0.1 times or less, more preferably 0.02 times or less, and still more preferably 0.01 times or less the concentration of Al in the film 44. Since the film 44 is the film to which the material removed during the etching of the lower electrode 12 is adhered, the concentration of Si, which is the constituent element of the insertion films 18 and 18a, is lower than that of the films 43 and 43a, for example, 0.9 times or less the concentration of Si in the films 43 and 43a.

In the first embodiment and the modifications thereof, the insertion films 18 and 18a are silicon oxide films which are oxides of Si. In this case, the insulating properties of the films 43 and 43a, which are the films to which the materials removed during the etching of the insertion films 18 and 18a are adhered, can be improved. Therefore, the electrical connection between the film 41 and the film 44 is suppressed, and the short-circuit between the lower electrode 12 and the upper electrode 16 can be suppressed. The insertion films 18 and 18a may be oxides of metal elements, or nitrides or carbides of metal elements, as long as the resistivities of the insertion films 18 and 18a are higher than those of the lower electrode 12 and the upper electrode 16. Specifically, the insulating film may be formed by containing at least one of silicon oxide (SiO₂), silicon nitride (SiN), aluminum nitride (AlN), aluminum oxide (Al₂O₃), tantalum oxide (Ta₂O₅), zirconium oxide (ZrO₂), silicon carbide (SiC), yttrium oxide (Y₂O₃), hafnium oxide (HfO₂), titanium oxide (TiO₂), magnesium oxide (MgO), titanium nitride (TiN), vanadium nitride (VN), chromium nitride (CrN), niobium nitride (NbN), molybdenum nitride (MoN), hafnium nitride (HfN), tantalum nitride (TaN), tungsten nitride (WN), titanium carbide (TiC), vanadium carbide (VC), chromium carbide (CrC), niobium carbide (NbC), molybdenum carbide (MoC), hafnium carbide (HfC), tantalum carbide (TaC), and tungsten carbide (WC). In the present specification, metalloids such as boron (B), silicon (Si), and germanium (Ge) are also considered to be the metal elements. The insertion films 18 and 18a may be metal films as long as they have resistivities higher than those of the lower electrode 12 and the upper electrode 16.

The insertion films 18 and 18a are preferably inorganic insulating films in view of enhancing the insulating properties of the films 43 and 43a. Specifically, the insertion films 18 and 18a are preferably formed to contain at least one of silicon oxide (SiO₂), silicon nitride (SiN), aluminum nitride (AlN), aluminum oxide (Al₂O₃), tantalum oxide (Ta₂O₅), zirconium oxide (ZrO₂), silicon carbide (SiC), yttrium oxide (Y₂O₃), hafnium oxide (HfO₂), titanium oxide (TiO₂), and magnesium oxide (MgO). The insulating film is a film having a resistivity of 10⁸ Ω·cm or more.

In the first embodiment and the modifications thereof, the piezoelectric layer 14 is a single crystal lithium tantalate layer or a single crystal lithium niobate layer. In this case, when the through hole 22 is formed in the piezoelectric layer 14, the ion milling method is used. Therefore, the material removed during the etching is likely to adhere to the side surfaces of the upper electrode 16 and the like to form the adhesion film. Accordingly, when the piezoelectric layer 14 is the single crystal lithium tantalate layer or the single crystal lithium niobate layer, it is preferable to form at least one of the insertion films 18 and 18a on at least one region between the lower electrode 12 and the piezoelectric layer 14 or between the piezoelectric layer 14 and the upper electrode 16. The piezoelectric layer 14 may be a layer other than the single crystal lithium tantalate layer and the single crystal lithium niobate layer, and may be, for example, an aluminum nitride layer, a zinc oxide layer, a lead zirconate titanate layer, or a lead titanate layer.

In the first embodiment and the modifications thereof, the lower electrode 12 and the upper electrode 16 excite the piezoelectric layer 14 in the resonance region 50 to generate the thickness-shear vibration. As illustrated in FIG. 1, two through holes 22 are provided with the resonance region 50 interposed therebetween, and the vibration direction 60 of the thickness-shear vibration is a direction (e.g., Y direction) intersecting a direction (e.g., X direction) in which the two through holes 22 face each other with the resonance region 50 interposed therebetween. This makes it possible to suppress the leakage of the acoustic wave from the resonance region 50.

In the first embodiment and the modification thereof, the maximum distance L (see FIG. 8) between the through hole 22 and the piezoelectric layer 14 in the resonance region 50 is 1.6, or less, that is, 3.2 times or less the thickness of the piezoelectric layer 14. This makes it possible to suppress the increase in size of the device while suppressing the deterioration of the device characteristics, as illustrated in FIG. 5. From the viewpoint of suppressing the deterioration of the device characteristics, the distance L is preferably 2.6 times or less, more preferably 1.6 times or less, and still more preferably 0.7 times or less the thickness of the piezoelectric layer 14.

### Second Embodiment

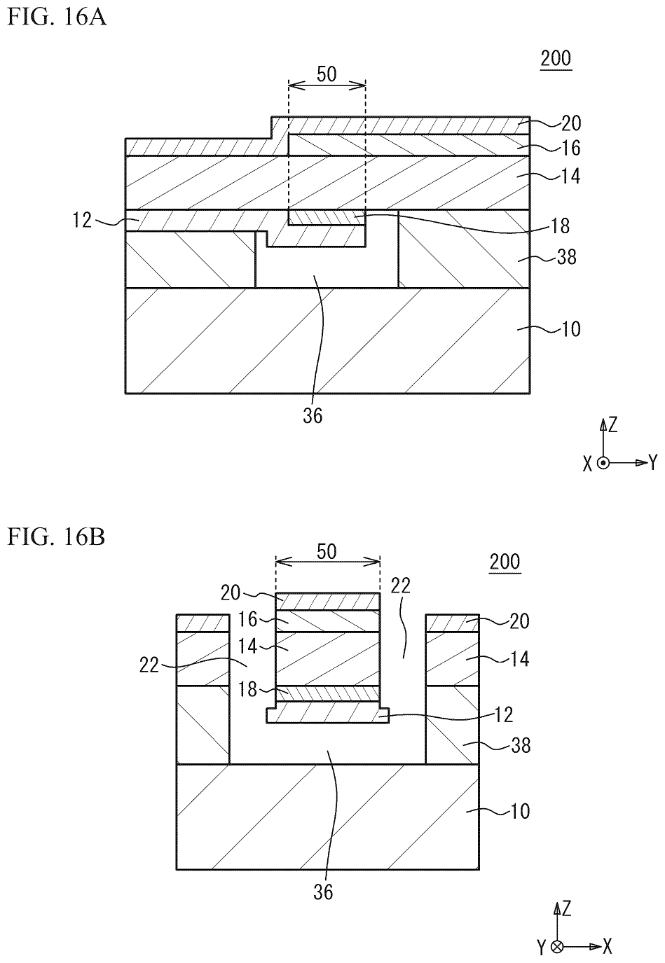

FIGS. 16A and 16B are cross-sectional views of an acoustic wave device 200 according to a second embodiment. As illustrated in FIGS. 16A and 16B, in the acoustic wave device 200 according to the second embodiment, an air gap 36 is provided instead of the acoustic reflection film 30. The air gap 36 is formed in, for example, an insulating film 38 provided on the substrate 10, and communicates with the through holes 22. The other components of the second embodiment are the same as those of the first embodiment, and therefore, the description thereof is omitted.

The acoustic wave device may be a Solidly Mounted Resonator (SMR) in which the acoustic reflection film 30 for reflecting the acoustic wave is provided under the lower electrode 12 as in the first embodiment and the modifications thereof, or may be a Film Bulk Acoustic Resonator (FBAR) in which the air gap 36 is provided under the lower electrode 12 as in the second embodiment.

### Third Embodiment

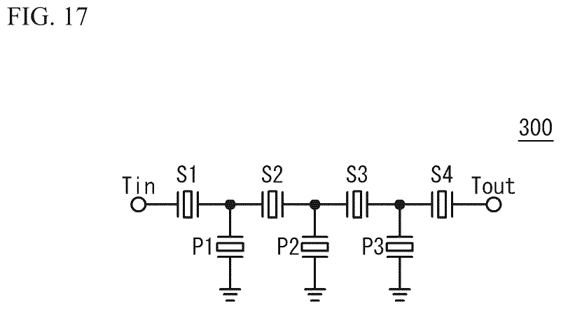

FIG. 17 is a circuit diagram of a filter 300 according to a third embodiment. As illustrated in FIG. 17, in the filter 300 according to the third embodiment, one or a plurality of series resonators S1 to S4 are connected in series between an input terminal Tin and an output terminal Tout. One or a plurality of parallel resonators P1 to P3 are connected in parallel between the input terminal Tin and the output terminal Tout. The acoustic wave device according to the first embodiment, the modifications of the first embodiment, or the second embodiment may be used for at least one of the series resonators S1 to S4 and the parallel resonators P1 to P3. The number of series resonators and parallel resonators can be set appropriately. Although the ladder type filter is illustrated as an example of the filter, the filter may be a multi-mode type filter.

In the third embodiment, the case where the acoustic wave device according to the first embodiment, the modifications of the first embodiment, and the second embodiment is used for the filter is described as an example, but the present disclosure is not limited to this case. For example, the acoustic wave device may be used for an actuator used in an inkjet micropump, an RF-MEMS switch or an optical mirror, or a sensor such as an acceleration sensor, a gyro sensor, or an energy harvest sensor.

### Fourth Embodiment

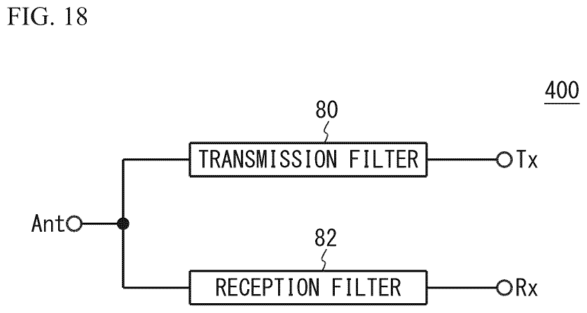

FIG. 18 is a circuit diagram of a duplexer 400 according to a fourth embodiment. As illustrated in FIG. 18, in the duplexer 400 according to the fourth embodiment, a transmission filter 80 is connected between a common terminal Ant and a transmission terminal Tx. A reception filter 82 is connected between the common terminal Ant and the reception terminal Rx. The transmission filter 80 passes a signal in a transmission band of the high frequency signals inputted from the transmission terminal Tx, to the common terminal Ant as a transmission signal, and suppresses signals of other frequencies. The reception filter 82 passes a signal in a reception band of the high frequency signals inputted from the common terminal Ant, to the reception terminal Rx as a reception signal, and suppresses signals of other frequencies. At least one of the transmission filter 80 and the reception filter 82 may be used as the filter of the second embodiment. Although the duplexer is illustrated as an example of a multiplexer, a triplexer or a quad duplexer may be used.

Although the embodiments of the present disclosure have been described in detail above, the present disclosure is not limited to the specific embodiments, and various modifications and changes can be made within the scope of the gist of the present disclosure described in the claims.

What is claimed is:

1. An acoustic wave device comprising:
a substrate;
a lower electrode provided above the substrate;
an upper electrode provided above the lower electrode;
a piezoelectric layer provided above the substrate with at least a part of the piezoelectric layer interposed between the lower electrode and the upper electrode, the piezoelectric layer having a through hole along a resonance region where the lower electrode and the upper electrode overlap with each other with the at least a part of the piezoelectric layer interposed therebetween in planar view, the through hole exposing at least a part of the lower electrode;
an insertion film provided either or both of between the lower electrode and the piezoelectric layer and between the upper electrode and the piezoelectric layer, the insertion film having a resistivity higher than resistivities of the lower electrode and the upper electrode;
a first film in contact with, and extending upward from, a side surface of the lower electrode to a side of a side surface of the upper electrode, the first film containing a constituent element of the lower electrode;
a second film in contact with, and extending upward from, a side surface of the piezoelectric layer to a region between the side surface of the upper electrode and the first film, the second film having a concentration of a constituent element of the piezoelectric layer higher than that of the first film; and
a third film in contact with, and extending upward from, a side surface of the insertion film so as to extend to at least one of a region between the side surface of the upper electrode and the second film and a region between the first film and the second film, wherein a concentration of a first element of the third film, which is a constituent element of the insertion film and different from a constituent element of the piezoelectric layer, is higher than that of the second film, and a concentration of a second element of the third film, which is the constituent element of the piezoelectric layer and different from the constituent element of the insertion film, is lower than that of the second film.

2. The acoustic wave device according to claim 1, wherein
the second film and the third film have a concentration of a constituent element of the lower electrode lower than that of the first film.

3. The acoustic wave device according to claim 1, wherein
the second film and the third film do not contain a constituent element of the lower electrode.

4. The acoustic wave device according to claim 1, wherein
the first film has a concentration of the constituent element of the insertion film lower than that of the third film.

5. The acoustic wave device according to claim 1, wherein
the insertion film is an inorganic insulating film.

6. The acoustic wave device according to claim 5, wherein
the insertion film is formed to contain at least one of silicon oxide, silicon nitride, aluminum nitride, aluminum oxide, tantalum oxide, zirconium oxide, silicon carbide, yttrium oxide, hafnium oxide, titanium oxide, and magnesium oxide.

7. The acoustic wave device according to claim 1, wherein
the piezoelectric layer is a single crystal lithium tantalate layer or a single crystal lithium niobate layer.

8. The acoustic wave device according to claim 7, wherein
the lower electrode and the upper electrode excite thickness-shear vibration in the piezoelectric layer in the resonance region,
two through holes are provided with the resonance region interposed therebetween, and
a vibration direction of the thickness-shear vibration is a direction intersecting a direction in which the two through holes face each other with the resonance region interposed therebetween.

9. The acoustic wave device according to claim 8, wherein
a maximum distance between the through hole and the piezoelectric layer in the resonance region is 3.2 times or less a thickness of the piezoelectric layer in the resonance region.

10. A filter comprising the acoustic wave device according to claim 1.

11. A multiplexer comprising the filter according to claim 10.

12. A method of manufacturing an acoustic wave device comprising:
forming a lower electrode, a piezoelectric layer, and an upper electrode in this order on a substrate;
forming an insertion film provided on at least one region between the lower electrode and the piezoelectric layer and between the piezoelectric layer and the upper electrode, the insertion film having a resistivity higher than those of the lower electrode and the upper electrode;
etching the piezoelectric layer, the insertion film, and the lower electrode on a side part of a resonance region where the lower electrode and the upper electrode overlap with the piezoelectric layer interposed therebetween so as to form a through hole in the piezoelectric layer along the resonance region such that a second film adhered by etching the piezoelectric layer is formed between a first film adhered by etching the lower electrode and a side surface of the upper electrode, and such that a third film adhered by etching the insertion film is formed on at least one of a region between the side surface of the upper electrode and the second film and a region between the first film and the second film.

13. The method of manufacturing the acoustic wave device according to claim 12, wherein
the piezoelectric layer, the insertion film and the lower electrode are etched by an ion milling method.
